(19) United States
(12) Patent Application Publication
(10) Pub. No.: US 2016/0075871 A1
(43) Pub. Date: Mar. 17, 2016

(54) THERMOSETTING RESIN COMPOSITION AND METHOD FOR PRODUCING A SEMICONDUCTOR DEVICE

(71) Applicant: NITTO DENKO CORPORATION, Ibaraki-shi, Osaka (JP)

(72) Inventors: Kosuke Morita, Ibaraki-shi (JP); Naohide Takamoto, Ibaraki-shi (JP); Hiroyuki Hanazono, Ibaraki-shi (JP); Akihiro Fukui, Ibaraki-shi (JP)

(21) Appl. No.: 14/784,892

(22) PCT Filed: Apr. 11, 2014
(86) PCT No.: PCT/JP2014/060477

§ 371 Date: Oct. 15, 2015

(30) Foreign Application Priority Data
Apr. 19, 2013 (JP) 2013-088636

(51) Int. Cl. C08L 61/06; H01L 23/00; H01L 23/29; H01L 21/56

(52) U.S. Cl. CPC C08L 61/06; H01L 21/56; H01L 24/83; H01L 23/293; C08L 2203/206; H01L 2224/2919; H01L 2224/2929; H01L 2224/32225; H01L 2224/83191; H01L 2224/83862; H01L 2924/0665; H01L 2924/066

(57) ABSTRACT

Provided are a thermosetting resin composition with which a semiconductor device having a high connection reliability can be provided while securing availability of member materials by reducing a difference in thermal-responsive behavior between a semiconductor element and an adherend, and a method for producing a semiconductor device using the thermosetting resin composition. The present invention provides a thermosetting resin composition for producing a semiconductor device, the thermosetting resin composition comprising: an epoxy resin; and a novolak-type phenol resin having a hydroxyl equivalent of 200 g/eq or more.

### TECHNICAL FIELD

The present invention relates to a thermosetting resin composition and a method for producing a semiconductor device.

### BACKGROUND ART

In recent years, demands for high-density mounting have been increased as electronic instruments have become smaller and thinner. Accordingly, for semiconductor packages, the surface mount type has become mainstream suitable for high-density mounting in place of the conventional pin insertion type. In the surface mount type, a lead is soldered directly to a printed board or the like. For a heating method, the whole of a package is heated by infrared reflow, vapor phase reflow, solder dip or the like to perform mounting.

After surface mounting, an under-fill material is filled in a space between a semiconductor element and a substrate for ensuring protection of the surface of the semiconductor element and connection reliability between the semiconductor element and the substrate. There has been proposed a technique for filling a space between a semiconductor element and a substrate with a sheet-like under-fill material in place of a liquid under-fill material in view of arrangement easiness and adjustment easiness of filling degree (Patent Document 1).

Generally, the following procedure is employed as a process using a sheet-like under-fill material, that is, a sheet-like under-fill material is attached to a semiconductor element, and a space between an adherend such as a substrate and the semiconductor element is filled with the sheet-like under-fill material integrated with the semiconductor element while connecting the semiconductor element to the adherend such as a substrate to perform mounting. In the process, the space between the adherend and the semiconductor element is easily filled with the under-fill material.

### PRIOR ART DOCUMENT

### Patent Document

Patent Document 1: JP-B-4438973

### SUMMARY OF THE INVENTION

### Problems to be Solved by the Invention

The semiconductor device may be made smaller and thinner by reducing the thickness of the semiconductor element, but influences of the thermal-responsive behavior of the adherend (warp and expansion, etc.) on the semiconductor element increase as the semiconductor element becomes thinner. This results from the fact that the thermal expansion coefficient of an adherend such as a substrate is generally higher than that of a semiconductor element. Particularly, stress resulting from a difference in thermal-responsive behavior between the semiconductor element and the adherend tends to localize on a connection member such as a solder bump for connecting the semiconductor element and the adherend, and the joint may be broken in some cases. As a measure against this, the materials and the like of the semiconductor element and the adherend can be selected so as to match the thermal-responsive behaviors of the former and the latter, but the range of materials that can be selected is limited.

An object of the present invention is to provide a thermosetting resin composition with which a semiconductor device having a high connection reliability can be provided while securing availability of member materials by reducing a difference in thermal-responsive behavior between a semiconductor element and an adherend, and a method for producing a semiconductor device using the thermosetting resin composition.

### Means for Solving the Problems

As a result of conducting vigorous studies on the problem, the present inventors have found that the aforementioned object can be achieved by employing the following configuration, thus leading to completion of the present invention.

The present invention provides a thermosetting resin composition for producing a semiconductor device, the thermosetting resin composition containing:

an epoxy resin; and

a novolak-type phenol resin having a hydroxyl equivalent of 200 g/eq or more.

Since the thermosetting resin composition contains the epoxy resin and the novolak-type phenol resin having a hydroxyl equivalent of 200 g/eq or more (hereinafter, also referred to as a “specific phenol resin”), the thermosetting resin composition can secure the rigidity of a cured product obtained by heat curing (hereinafter, merely also referred to as a “cured product”), and suppress the excessive cross-linkage between both the resins to exhibit moderate flexibility. This can provide a semiconductor device which can reduce the difference between the thermoresponsive behaviors of a semiconductor element and an adherend, suppress the fracture of a joined part, and provide high connection reliability. The difference between the thermoresponsive behaviors of the semiconductor element and the adherend can be reduced by using the thermosetting resin composition. Accordingly, this can broaden the choice of the materials of the semiconductor device and the adherend.

The thermosetting resin composition is suitable for sealing a semiconductor element.

In the thermosetting resin composition, the novolak-type phenol resin preferably includes a structure represented by the following structural formula:

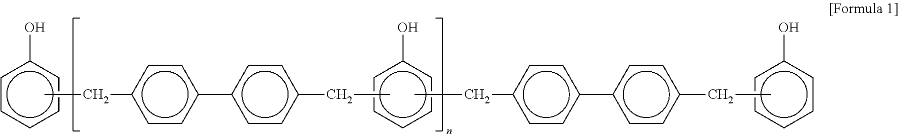

wherein n is an integer of 0 to 12.

The balance between the rigidity and flexibility of the cured product can be achieved at a higher level by using the novolak-type phenol resin having the specific structure, and the reliability of the semiconductor device can be further improved.

The thermosetting resin composition preferably contains an inorganic filler having an average particle diameter of 10 nm or more and 1000 nm or less. The thermosetting resin composition contains the inorganic filler, which can provide a reduction in the thermal expansion coefficient of the cured product, and suppress the influence of the thermoresponsive behavior caused by the cured product itself to provide a further improvement in the reliability of the semiconductor device. By setting the average particle diameter of the inorganic filler within the above range, the thermosetting resin composition having good transparency is provided, and as a result, the dicing position of a wafer and the position of the semiconductor element to be mounted on the adherend can be easily aligned.

The thermosetting resin composition preferably has a thermal expansion coefficient α of 10 ppm/K or more and 200 ppm/K or less after being heat-treated at 175° C. for 1 hour. By setting the thermal expansion coefficient α of the cured product within the above range, the thermoresponsive behavior caused by the cured product itself can be suppressed, and as a result, the reliability of the semiconductor device can be further improved.

The thermosetting resin composition preferably has a storage elastic modulus E′ of 100 MPa or more and 10000 MPa or less after being heat-treated at 175° C. for 1 hour. This provides the cured product with moderate rigidity, and the absorption or dispersion of the difference between the thermoresponsive behaviors is promoted to further improve the reliability of the semiconductor device.

The thermosetting resin composition is preferably a sheet-like thermosetting resin composition. This provides good workability, and the sheet-like composition is easily disposed in a space between the semiconductor device and the adherend, so that the production efficiency of the semiconductor device can be improved.

The present invention also includes a method for producing a semiconductor device, the method comprising:

a fixing step of fixing a semiconductor element to an adherend with the thermosetting resin composition interposed therebetween; and

a curing step of curing the thermosetting resin composition.

By producing a semiconductor device using the thermosetting resin composition, the difference among the thermoresponsive behaviors of the semiconductor element, the cured product of the thermosetting resin composition, and the adherend can be reduced, and a semiconductor device having excellent reliability can be efficiently produced.

### BRIEF DESCRIPTION OF THE DRAWINGS

FIG. 1 is a sectional schematic view showing a sealing sheet having a thermosetting resin composition according to one embodiment of the present invention;

FIG. 2A is a sectional schematic view showing a step for producing a semiconductor device according to one embodiment of the present invention;

FIG. 2B is a sectional schematic view showing a step for producing a semiconductor device according to one embodiment of the present invention;

FIG. 2C is a sectional schematic view showing a step for producing a semiconductor device according to one embodiment of the present invention;

FIG. 2D is a sectional schematic view showing a step for producing a semiconductor device according to one embodiment of the present invention;

FIG. 2E is a sectional schematic view showing a step for producing a semiconductor device according to one embodiment of the present invention;

FIG. 2F is a sectional schematic view showing a step for producing a semiconductor device according to one embodiment of the present invention;

FIG. 3A is a sectional schematic view showing a step for producing a semiconductor device according to another embodiment of the present invention;

FIG. 3B is a sectional schematic view showing a step for producing a semiconductor device according to another embodiment of the present invention;

FIG. 3C is a sectional schematic view showing a step for producing a semiconductor device according to another embodiment of the present invention;

FIG. 3D is a sectional schematic view showing a step for producing a semiconductor device according to another embodiment of the present invention;

### MODE FOR CARRYING OUT THE INVENTION

Hereinafter, one embodiment of the present invention will be described below taking as an example a sealing sheet having a sheet-like thermosetting resin composition integrated with back surface grinding tape and a method for producing a semiconductor device using the sealing sheet. Descriptions below can also be applied to the case of a thermosetting resin composition alone, in principle.

<Sealing Sheet>

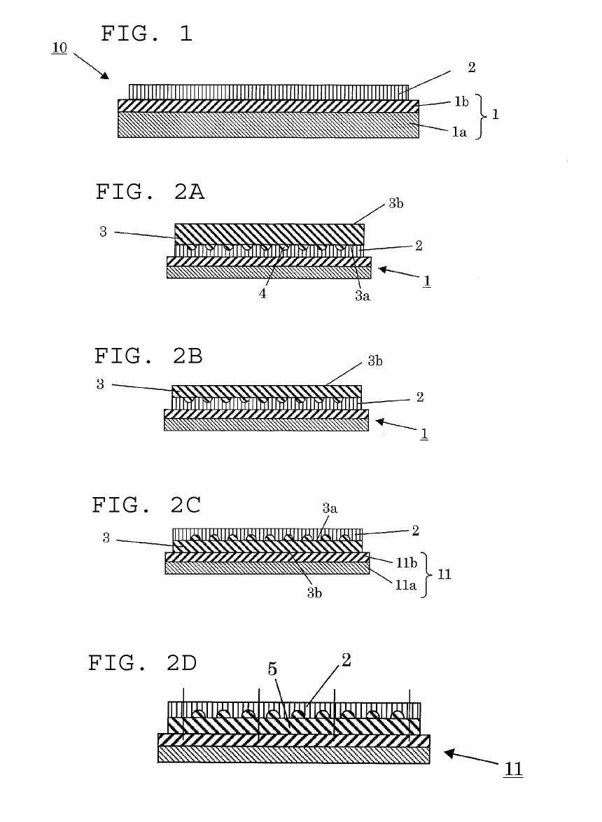

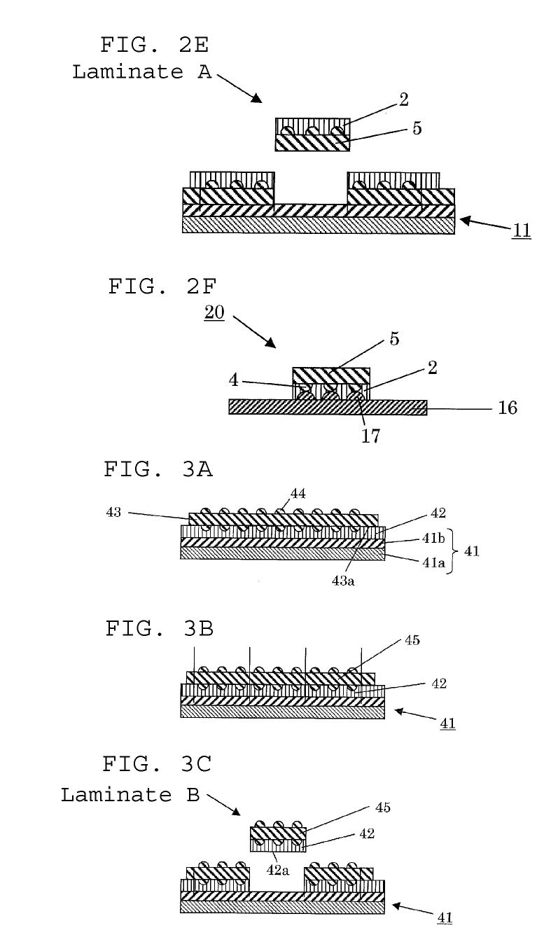

As shown in FIG. 1, a sealing sheet 10 has a back surface grinding tape 1 and a sheet-like thermosetting resin composition 2 laminated on the back surface grinding tape 1. The thermosetting resin composition 2 is not necessarily laminated on the entire surface of the back surface grinding tape 1 as shown in FIG. 1, but may be provided in a size sufficient for bonding with a semiconductor wafer 3 (see FIG. 2A).

[Thermosetting Resin Composition]

The thermosetting resin composition 2 in the present embodiment is a sheet-like thermosetting resin composition, and can be suitably used as a sealing film with which a space between a semiconductor element subjected to surface mounting (for example, flip chip mounting or the like) and an adherend is filled, or as an adhesive film for fixing a semiconductor element to an adherend.

The thermosetting resin composition 2 contains an epoxy resin and a novolak-type phenol resin having a hydroxyl equivalent of 200 g/eq or more, and may contain a heat curing accelerating catalyst, a flux agent, a cross-linking agent, and an inorganic filler or the like if necessary.

(Epoxy Resin)

The epoxy resin is not particularly limited as long as it is usable as a thermosetting resin, and for example a difunctional epoxy resin or a polyfunctional epoxy resin such as a bisphenol A type, a bisphenol F type, a bisphenol S type, a brominated bisphenol A type, a hydrogenated bisphenol A type, a bisphenol AF type, a biphenyl type, a naphthalene type, a fluorene type, a phenol novolak type, an orthocresol novolak type, a trishydroxyphenyl methane type or a tetraphenylol ethane type, or an epoxy resin such as a hydantoin type, a trisglycidyl isocyanurate type or a glycidyl amine type may be used. They can be used alone, or in combination of two or more thereof. Among these epoxy resins, a novolak type epoxy resin, a biphenyl type epoxy resin, a trishydroxyphenyl methane type resin or a tetraphenylol ethane type epoxy resin is especially preferable. This is because the aforementioned resins have a high reactivity with a phenol resin as a curing agent, and are excellent in heat resistance and so on.

(Novolak-Type Phenol Resin Having Hydroxyl Equivalent of 200 g/eq or More)

The novolak-type phenol resin contained in the thermosetting resin composition 2 acts as a curing agent for the epoxy resin. As long as the hydroxyl equivalent is 200 g/eq or more, the novolak-type phenol resin is not particularly limited. The novolak-type phenol resin having a hydroxyl equivalent of 200 g/eq or more is obtained by reaction of a phenol with a compound capable of being subjected to a condensation reaction with the phenol and having a moderate molecular chain length (for example, aldehyde and bis(alkoxymethyl)biphenyl) according to a typical method. A commercially available novolak-type phenol resin having a hydroxyl equivalent of 200 g/eq or more can also be suitably used. Examples thereof include “SN-495” manufactured by Nippon Steel Chemical Co., Ltd. and “MEH-7851H” manufactured by Meiwa Plastic Industries, ltd. The upper limit of the hydroxyl equivalent is not particularly limited, and may be preferably 250 g/eq or less in view of the curability of the thermosetting resin composition, and the rigidity of the cured product thereof, or the like.

Above all, the novolak-type phenol resin preferably includes a structure represented by the following structural formula:

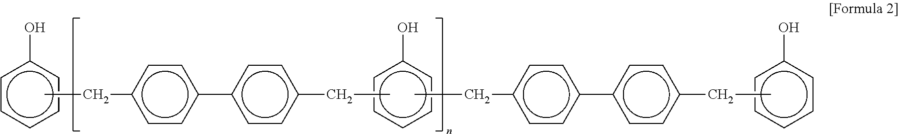

wherein n is an integer of 0 to 12.

The balance between the rigidity and flexibility of the cured product can be achieved at a higher level by using the novolak-type phenol resin having the specific structure, and the reliability of the semiconductor device can be further improved. In the above formula, n may be any integer of 0 to 12. However, n is preferably an integer of 0 to 8.

(Other Resins)

The thermosetting resin composition 2 can contain a thermosetting resin and a thermoplastic resin other than the epoxy resin and the specific phenol resin.

(Other Thermosetting Resins)

Examples of other thermosetting resins include an amino resin, an unsaturated polyester resin, a polyurethane resin, a silicone resin and a thermosetting polyimide resin. These resins can be used alone, or in combination of two or more thereof.

In addition to the specific novolak-type phenol resin, phenol resins such as a phenolaralkyl resin, a novolak-type phenol resin (e.g., a cresol novolak resin, a tert-butylphenol novolak resin, or a nonylphenol novolak resin), a resol type phenol resin, and polyoxy styrene (e.g., polyparaoxystyrene) can be used singly or in combination as the phenol resin, as long as the effects of the present invention are not impaired.

For example, the epoxy resin and the specific phenol resin are preferably blended at such a blending ratio that the equivalent of the hydroxyl group in the specific phenol resin per one equivalent of the epoxy group in the epoxy resin component is 0.5 to 2.0 equivalents. More preferable is 0.8 to 1.2 equivalents. That is, if the blending ratio of the resins falls out of the aforementioned range, the curing reaction does not proceed sufficiently, so that properties of cured products of the thermosetting resin composition are easily deteriorated.

(Thermoplastic Resin)

Examples of the thermoplastic resin include natural rubber, butyl rubber, isoprene rubber, chloroprene rubber, an ethylene-vinyl acetate copolymer, an ethylene-acrylic acid copolymer, an ethylene-acrylate copolymer, a polybutadiene resin, a polycarbonate resin, a thermoplastic polyimide resin, polyamide resins such as 6-nylon and 6,6-nylon, a phenoxy resin, an acrylic resin, saturated polyester resins such as PET and PBT, a polyamideimide resin, and a fluororesin. These thermoplastic resins can be used alone, or in combination of two or more thereof. Among these thermoplastic resins, an acrylic resin, which has reduced ionic impurity, has a high heat resistance, and can ensure the reliability of a semiconductor element, is especially preferable.

The acrylic resin is not particularly limited, and examples thereof include polymers having as a component one or more of esters of acrylic acids or methacrylic acids which have a linear or branched alkyl group having 30 or less of carbon atoms, especially 4 to 18 carbon atoms. Examples of the alkyl group include a methyl group, an ethyl group, a propyl group, an isopropyl group, an n-butyl group, a t-butyl group, an isobutyl group, an amyl group, an isoamyl group, a hexyl group, a heptyl group, a cyclohexyl group, a 2-ethylhexyl group, an octyl group, an isooctyl group, a nonyl group, an isononyl group, a decyl group, an isodecyl group, an undecyl group, a lauryl group, a tridecyl group, a tetradecyl group, a stearyl group, an octadecyl group and a dodecyl group.

Other monomers for forming the polymer are not particularly limited, and examples thereof include cyano group-containing monomers such as acrylonitrile, carboxyl group-containing monomers such as acrylic acid, methacrylic acid, carboxyethyl acrylate, carboxypentyl acrylate, itaconic acid, maleic acid, fumaric acid and crotonic acid, acid anhydride monomers such as maleic anhydride and itaconic anhydride, hydroxyl group-containing monomers such as 2-hydroxyethyl(meth)acrylate, 2-hydroxypropyl(meth)acrylate, 4-hydroxybutyl(meth)acrylate, 6-hydroxyhexyl(meth)acrylate, 8-hydroxyoctyl(meth)acrylate, 10-hydroxydecyl(meth)acrylate, 12-hydroxylauryl(meth)acrylate and (4-hydroxymethylcyclohexyl)-methyl acrylate, sulfonic acid group-containing monomers such as styrenesulfonic acid, allylsulfonic acid, 2-(meth)acrylamide-2-methylpropanesulfonic acid, (meth)acrylamidepropanesulfonic acid, sulfopropyl (meth)acrylate and (meth)acryloyloxynaphthalenesulfonic acid, and phosphoric acid group-containing monomers such as 2-hydroxyethylacryloyl phosphate.

In the present embodiment, a thermosetting resin composition using the epoxy resin, the specific phenol resin and the acrylic resin is especially preferable. These resins have reduced ionic impurity and have a high heat resistance, and therefore can ensure the reliability of a semiconductor element. The blending ratio in this case is such that the mixed amount of the epoxy resin and the specific phenol resin is 10 to 200 parts by weight based on 100 parts by weight of the acrylic resin component.

(Heat Curing Accelerating Catalyst)

A heat curing accelerating catalyst for the epoxy resin and the specific phenol resin is not particularly limited, and can be appropriately selected from known heat curing accelerating catalysts and used. The heat curing accelerating catalyst can be used alone, or in combination or two or more kinds. As the heat curing accelerating catalyst, for example, an amine-based curing accelerator, a phosphorus-based curing accelerator, an imidazole-based curing accelerator, a boron-based curing accelerator or phosphorus-boron-based curing accelerator can be used. An addition amount of the heat curing accelerating catalyst is 0.1 to 5 parts by weight based on 100 parts by weight of the total amount of the epoxy resin and the specific phenol resin.

(Flux Agent)

A flux agent may be added to the thermosetting resin composition 2 for removing an oxide film on the surface of a solder bump to facilitate mounting of a semiconductor element. The flux agent is not particularly limited, a previously known compound having an a flux action can be used, and examples thereof include diphenolic acid, adipic acid, acetylsalicylic acid, benzoic acid, benzilic acid, azelaic acid, benzylbenzoic acid, malonic acid, 2,2-bis(hydroxymethyl)propionic acid, salicylic acid, o-methoxybenzoic acid, m-hydroxybenzoic acid, succinic acid, 2,6-dimethoxymethyl paracresol, hydrazide benzoate, carbohydrazide, dihydrazide malonate, dihydrazide succinate, dihydrazide glutarate, hydrazide salicylate, dihydrazide iminodiacetate, dihydrazide itaconate, trihydrazide citrate, thiocarbohydrazide, benzophenone hydrazone, 4,4′-oxybisbenzenesulfonyl hydrazide and dihydrazide adipate. The added amount of the flux agent may be such an amount that the flux action is exhibited, and is normally about 0.1 to 20 parts by weight based on 100 parts by weight of the resin component contained in the thermosetting resin composition.

(Crosslinker)

When the thermosetting resin composition 2 of this embodiment is preliminarily crosslinked to a degree, a polyfunctional compound that reacts with a functional group or the like at the end of the molecular chain of a polymer should be added as a crosslinker at the time of preparation. Consequently, adhesion properties under a high temperature can be improved to improve the heat resistance.

As the crosslinker, particularly polyisocyanate compounds such as tolylene diisocyanate, diphenylmethane diisocyanate, p-phenylene diisocyanate, 1,5-naphthalene diisocyanate and an adduct of a polyhydric alcohol and a diisocyanate are more preferable. Preferably, the added amount of the crosslinker is normally 0.05 to 7 parts by weight based on 100 parts by weight of the polymer. If the amount of crosslinker is more than 7 parts by weight, the adhering strength is reduced, thus being not preferable. On the other hand, if the amount of the crosslinker is less than 0.05 parts by weight, the cohesive strength becomes poor, thus being not preferable. Other polyfunctional compounds such as an epoxy resin may be included as necessary together with the above-mentioned polyisocyanate compound.

(Inorganic Filler)

An inorganic filler can be appropriately blended with the thermosetting resin composition 2. Blending of the inorganic filler allows impartment of electrical conductivity, improvement of thermal conductivity, adjustment of a storage elastic modulus, and so on.

Examples of the inorganic filler include various inorganic powders made of ceramics such as silica, clay, plaster, calcium carbonate, barium sulfate, aluminum oxide, beryllium oxide, silicon carbide and silicon nitride, metals such as aluminum, copper, silver, gold, nickel, chromium, lead, tin, zinc, palladium and solder, or alloys, and carbon. They can be used alone, or in combination of two or more thereof. Above all, silica, particularly fused silica, is suitably used.

The average particle diameter of the inorganic filler is not particularly limited, but is preferably in a range of 10 nm or more and 1000 nm or less, more preferably in a range of 20 nm or more and 200 nm or less, and still more preferably in a range of 30 nm or more and 100 nm or less. If the average particle diameter of the inorganic filler is less than 10 nm, it would be a cause of decreasing the flexibility of the thermosetting resin composition. On the other hand, if the average particle diameter is more than 1000 nm, it would be a factor of decreasing the transparency of the thermosetting resin composition and decreasing a sealing property, as the particle diameter would be large with respect to a gap to be sealed by the thermosetting resin composition. In the present embodiment, inorganic fillers having mutually different average particle diameters may be combined and used. The average particle diameter is a value determined by a photometric particle size analyzer (manufactured by HORIBA, Ltd.; Unit Name: LA-910).

The blending amount of the inorganic filler is preferably 10 to 400 parts by weight, more preferably 50 to 250 parts by weight, based on 100 parts by weight of the organic resin component. If the blending amount of the inorganic filler is less than 10 parts by weight, the storage elastic modulus may be reduced, thereby considerably deteriorating the stress reliability of a package. On the other hand, if the blending amount of the inorganic filler is more than 400 parts by weight, the fluidity of the thermosetting resin composition 2 may be depressed, so that the thermosetting resin composition may not sufficiently fill up raised and recessed portions of the substrate or semiconductor element, thus leading to generation of voids and cracks.

(Other Additives)

Besides the inorganic filler, other additives can be blended with the thermosetting resin composition 2 as necessary. Examples of other additives include a flame retardant, a silane coupling agent and an ion trapping agent. Examples of the flame retardant include antimony trioxide, antimony pentaoxide and a brominated epoxy resin. They can be used alone, or in combination of two or more thereof. Examples of the silane coupling agent include β-(3,4-epoxycyclohexyl)ethyltrimethoxysilane, γ-glycidoxypropyltrimethoxysilane and γ-glycidoxypropylmethyldiethoxysilane. These compounds can be used alone, or in combination of two or more thereof. Examples of the ion trapping agent include a hydrotalcite and bismuth hydroxide. They can be used alone, or in combination of two or more thereof.

In this embodiment, the thermosetting resin composition 2 may be colored as necessary. In the thermosetting resin composition 2, the color shown by coloring is not particularly limited, but is preferably, for example, black, blue, red and green. For coloring, a colorant can be appropriately selected from known colorants such as pigments and dyes and used.

(Physical Properties of Thermosetting Resin Composition)

The thermosetting resin composition before heat curing has a haze of preferably 70% or less, more preferably 50% or less, and still more preferably 30% or less. The haze of the thermosetting resin composition is reduced to improve the transparency of the thermosetting resin composition, and thereby the semiconductor element can be more easily aligned in dicing and mounting. The haze of each of the thermosetting resin compositions is measured using a haze meter HM-150 (manufactured by Murakami Color Research Laboratory). The haze is measured in accordance with JIS K 7136.

The cured product obtained by heat-treating the thermosetting resin composition at 175° C. for 1 hour has a thermal expansion coefficient α of preferably 10 ppm/K or more and 200 ppm/K or less, more preferably 10 ppm/K or more and 100 ppm/K or less, and still more preferably 10 ppm/K or more and 50 ppm/K or less without particular limitation. By setting the thermal expansion coefficient α of the cured product in the above range, the thermoresponsive behavior caused by the cured product itself can be suppressed, and as a result, the reliability of the semiconductor device can be further improved.

The cured product obtained by heat-treating the thermosetting resin composition at 175° C. for 1 hour has a storage elastic modulus E′ of preferably 100 MPa or more and 10000 MPa or less, more preferably 500 MPa or more and 7000 MPa or less, and still more preferably 1000 MPa or more and 5000 MPa or less without particular limitation. This provides the cured product with moderate rigidity, and the absorption or dispersion of the difference between the thermoresponsive behaviors can be promoted to further improve the reliability of the semiconductor device.

The glass transition temperature (Tg) of the thermosetting resin composition after heat curing treatment at 175° C. for 1 hour is preferably 100 to 180° C., and more preferably 130 to 170° C. By setting the glass transition temperature of the thermosetting resin composition after heat curing within the above range, an abrupt change in properties within a temperature range in a heat cycle reliability test can be suppressed, so that a further improvement in reliability can be expected.

In this embodiment, the minimum melt viscosity of the thermosetting resin composition 2 at 100 to 200° C. before heat curing is preferably 100 Pa·s to 20000 Pa·s inclusively, more preferably 1000 Pa·s to 10000 Pa·s inclusively. By ensuring that the minimum melt viscosity is in the above-mentioned range, penetration of a connection member 4 into the thermosetting resin composition 2 (see FIG. 2A) can be facilitated. In addition, generation of voids at the time of electrical connection of a semiconductor element 5, and protrusion of the thermosetting resin composition 2 from a space between the semiconductor element 5 and an adherend 6 can be prevented (see FIG. 2E). In addition, the measurement of the minimum melt viscosity is a value measured by a parallel plate method using a rheometer (RS-1 manufactured by HAAKE, INC.). More specifically, the melt viscosity was measured in a range from 60° C. to 200° C. under conditions of gap: 100 μm; rotation plate diameter: 20 mm; rotation speed: 10 s⁻¹; and temperature rise rate: 10° C./minute, and the minimum value of melt viscosities in a range from 100° C. to 200° C. obtained at this time was designated as a minimum melt viscosity.

The viscosity of the thermosetting resin composition 2 at 23° C. before heat curing is preferably 0.01 M Pa·s to 100 M Pa·s inclusively, more preferably 0.1 M Pa·s to 10 M Pa·s inclusively. The thermosetting resin composition before heat curing has a viscosity in the above-mentioned range, whereby the retention property of a semiconductor wafer 3 (see FIG. 2C) at the time of dicing and the handling property at the time of operation can be improved. In addition, the measurement of the viscosity can be performed according to the method for measuring the minimum melt viscosity.

Further, the water absorption rate of the thermosetting resin composition 2 at a temperature of 23° C. and a humidity of 70% before heat curing is preferably 1% by weight or less, more preferably 0.5% by weight or less. The thermosetting resin composition 2 has such a water absorption rate as described above, whereby absorption of moisture into the thermosetting resin composition 2 can be suppressed, so that generation of voids during mounting of the semiconductor element 5 can be more efficiently suppressed. The lower limit of the water absorption rate is preferably as low as possible, and is preferably substantially 0% by weight, more preferably 0% by weight.

The thickness of the thermosetting resin composition 2 (total thickness in the case of a multiple layer) is not particularly limited, but may be about 10 μm to 100 μm when considering the strength of the thermosetting resin composition 2 and performance of filling a space between the semiconductor element 5 and the adherend 6. The thickness of the thermosetting resin composition 2 may be appropriately set in consideration of the gap between the semiconductor element 5 and the adherend 6 and the height of the connection member.

The thermosetting resin composition 2 of the sealing sheet 10 is preferably protected by a separator (not shown). The separator has a function as a protective material for protecting the thermosetting resin composition 2 until practical use. The separator is peeled off when the semiconductor wafer 3 is attached onto the thermosetting resin composition 2 of the sealing sheet. As the separator, polyethylene terephthalate (PET), polyethylene, polypropylene, or a plastic film or paper of which surface is coated with a release agent such as a fluorine-based release agent or a long-chain alkyl acrylate-based release agent can be used.

[Back Surface Grinding Tape]

The back surface grinding tape 1 includes a base material 1a, and a pressure-sensitive adhesive layer 1b laminated on the base material 1a. The thermosetting resin composition 2 is laminated on the pressure-sensitive adhesive layer 1b.

(Base Material)

The base material 1a is a reinforcement matrix for the sealing sheet 10. Examples include polyolefins such as low-density polyethylene, linear polyethylene, medium-density polyethylene, high-density polyethylene, very low-density polyethylene, random copolymerized polypropylene, block copolymerized polypropylene, homo polypropylene, polybutene and polymethylpentene, an ethylene-vinyl acetate copolymer, an ionomer resin, an ethylene-(meth)acrylic acid copolymer, an ethylene-(meth)acrylate (random, alternating) copolymer, an ethylene-butene copolymer, an ethylene-hexene copolymer, polyurethane, polyesters such as polyethylene terephthalate and polyethylene naphthalate, polycarbonate, polyimide, polyether ether ketone, polyimide, polyetherimide, polyamide, total aromatic polyamide, polyphenyl sulfide, alamid (paper), glass, glass cloth, a fluororesin, polyvinyl chloride, polyvinylidene chloride, a cellulose-based resin, a silicone resin, a metal (foil), and papers such as glassine paper. When the pressure-sensitive adhesive layer 1b is of an ultraviolet-ray curing type, the base material 1a is preferably one having a permeability to ultraviolet rays.

In addition, examples of the material of the base material 1a include polymers such as crosslinked products of the resins described above. For the plastic film described above, an unstretched film may be used, or a film subjected to uniaxial or biaxial stretching may be used as necessary.

The surface of the base material 1a can be subjected to a common surface treatment, for example, a chemical or physical treatment such as a chromic acid treatment, ozone exposure, flame exposure, high-voltage electrical shock exposure or an ionized radiation treatment, or a coating treatment with a primer (e.g., adhesive substance) for improving adhesion with an adjacent layer, the retention property and so on.

For the base material 1a, the same material or different materials can be appropriately selected and used, and one obtained by blending several materials can be used as necessary. The base material 1a can be provided thereon with a vapor-deposited layer of an electrically conductive substance made of a metal, an alloy, an oxide thereof, or the like and having a thickness of about 30 to 500 Å for imparting an antistatic property. The base material 1a may be a single layer or a multiple layer having two or more layers.

The thickness of the base material 1a is not particularly limited, and can be appropriately determined, but is generally about 5 to 200 μm, and is preferably 35 to 120 μm.

The base material 1a may contain various kinds of additives (e.g., colorant, filler, plasticizer, antiaging agent, antioxidant, surfactant, flame retardant, etc.) within the bounds of not impairing the effect of the present invention.

(Pressure-Sensitive Adhesive Layer)

A pressure-sensitive adhesive used for forming the pressure-sensitive adhesive layer 1b is not particularly limited as long as it can tightly hold a semiconductor wafer or a semiconductor chip through a thermosetting resin composition at the time of dicing, and provide control so that the semiconductor chip with the thermosetting resin composition can be peeled off during pickup. For example, a general pressure-sensitive adhesive such as an acryl-based pressure-sensitive adhesive or a rubber-based pressure-sensitive adhesive can be used. As the pressure-sensitive adhesive, an acryl-based pressure-sensitive adhesive having an acryl-based polymer as a base polymer is preferable from the viewpoint of ease of cleaning of an electronic component sensitive to contamination, such as a semiconductor wafer or glass, using ultrapure water or an organic solvent such as an alcohol.

Examples of the acryl-based polymer include those using an acrylate as a main monomer component. Examples of the acrylate include one or more of (meth)acrylic acid alkyl esters (for example, linear or branched alkyl esters with the alkyl group having 1 to 30, particularly 4 to 18 carbon atoms, such as methyl ester, ethyl ester, propyl ester, isopropyl ester, butyl ester, isobutyl ester, s-butyl ester, t-butyl ester, pentyl ester, isopentyl ester, hexyl ester, heptyl ester, octyl ester, 2-ethylhexyl ester, isooctyl ester, nony ester, decyl ester, isodecyl ester, undecyl ester, dodecyl ester, tridecyl ester, tetradecyl ester, hexadecyl ester, octadecyl ester and eicosyl ester) and (meth)acrylic acid cycloalkyl esters (for example, cyclopentyl ester and cyclohexyl ester, etc.). The (meth)acrylic acid ester refers to an acrylic acid ester and/or a methacrylic acid ester, and (meth) has the same meaning throughout the present invention.

The acryl-based polymer may contain a unit corresponding to any other monomer component capable of being copolymerized with the (meth)acrylic acid alkyl ester or cycloalkyl ester as necessary for the purpose of modifying cohesive strength, heat resistance and so on. Examples of the monomer component include carboxyl group-containing monomers such as acrylic acid, methacrylic acid, carboxyethyl (meth)acrylate, carboxypentyl (meth)acrylate, itaconic acid, maleic acid, fumaric acid and crotonic acid; acid anhydride monomers such as maleic anhydride and itaconic anhydride; hydroxyl group-containing monomers such as 2-hydroxyethyl(meth)acrylate, 2-hydroxypropyl(meth)acrylate, 4-hydroxybutyl(meth)acrylate, 6-hydroxyhexyl(meth)acrylate, 8-hydroxyoctyl(meth)acrylate, 10-hydroxydecyl(meth)acrylate, 12-hydroxylauryl(meth)acrylate and (4-hydroxymethylcyclohexyl)-methyl(meth)acrylate; sulfonic acid group-containing monomers such as styrenesulfonic acid, allylsulfonic acid, 2-(meth)acrylamide-2-methylpropanesulfonic acid, (meth)acrylamidepropanesulfonic acid, sulfopropyl (meth)acrylate and (meth)acryloyloxynaphthalenesulfonic acid; phosphoric acid group-containing monomers such as 2-hydroxyethylacryloyl phosphate; and acrylamide and acrylonitrile. One or more of these monomers capable of being copolymerized can be used. The used amount of the monomer component capable of copolymerization is preferably 40% by weight or less based on total monomer components.

Further, the acryl-based polymer may contain a polyfunctional monomer or the like as a monomer component for copolymerization as necessary for the purpose of crosslinking. Examples of the polyfunctional monomer include hexanediol di(meth)acrylate, (poly)ethylene glycol di(meth)acrylate, (poly)propylene glycol di(meth)acrylate, neopentylglycol di(meth)acrylate, pentaerythrithol di(meth)acrylate, trimethylolpropane tri(meth)acrylate, pentaerythrithol tri(meth)acrylate, dipentaerythrithol hexa(meth)acrylate, epoxy (meth)acrylate, polyester (meth)acrylate and urethane (meth)acrylate. One or more of these polyfunctional monomers can be used. The used amount of the polyfunctional monomer is preferably 30% by weight or less based on total monomer components from the viewpoint of an adhesion property.

The acryl-based polymer is obtained by subjecting a single monomer or monomer mixture of two or more kinds of monomers to polymerization. Polymerization can be carried out by any method such as solution polymerization, emulsion polymerization, bulk polymerization or suspension polymerization. The content of low-molecular weight substances is preferably low from the viewpoint of prevention of contamination of a clean adherend. In this respect, the number average molecular weight of the acryl-based polymer is preferably 300,000 or more, further preferably about 400,000 to 3,000,000.

For the pressure-sensitive adhesive, an external crosslinker can also be appropriately employed for increasing the number average molecular weight of an acryl-based polymer or the like as a base polymer. Specific examples of the external crosslinking methods include a method in which so called a crosslinker such as a polyisocyanate compound, an epoxy compound, an aziridine compound or a melamine-based crosslinker is added and reacted. When an external crosslinker is used, the used amount thereof is appropriately determined according to a balance with a base polymer to be crosslinked, and further a use application as a pressure-sensitive adhesive. Generally, the external crosslinker is blended in an amount of preferably about 5 parts by weight or less, further preferably 0.1 to 5 parts by weight, based on 100 parts by weight of the base polymer. Further, for the pressure-sensitive adhesive, previously known various kinds of additives, such as a tackifier and an anti-aging agent, may be used as necessary in addition to the aforementioned components.

The pressure-sensitive adhesive layer 1b can be formed by radiation curing-type pressure-sensitive adhesive. By irradiating the radiation curing-type pressure-sensitive adhesive with radiations such as ultraviolet rays, the degree of crosslinking thereof can be increased to easily reduce its adhesive power, so that pickup can be easily performed. Examples of radiations include X-rays, ultraviolet rays, electron rays, α rays, β rays and neutron rays.

For the radiation curing-type pressure-sensitive adhesive, one having a radiation-curable functional group such as a carbon-carbon double bond and showing adherability can be used without particular limitation. Examples of the radiation curing-type pressure-sensitive adhesive may include, for example an addition-type radiation-curable pressure-sensitive adhesive obtained by blending a radiation-curable monomer component or an oligomer component with a general pressure-sensitive adhesive such as the above-mentioned acryl-based pressure-sensitive adhesive or rubber-based pressure-sensitive adhesive.

Examples of the radiation curable monomer component to be blended include urethane oligomer, urethane (meth)acrylate, trimethylolpropane tri(meth)acrylate, tetramethylolmethane tetra(meth)acrylate, pentaerythrithol tri(meth)acrylate, pentaerythrithol tetra(meth)acrylate, dipentaerythrithol monohydroxypenta(meth)acrylate, dipentaerythrithol hexa(meth)acrylate and 1,4-butanediol di(meth)acrylate. Examples of the radiation curable oligomer component include various oligomers such as urethane-based, polyether-based, polyester-based, polycarbonate-based and polybutadiene-based oligomers, and the appropriate weight-average molecular weight thereof is in a range of about 100 to 30,000. For the blending amount of the radiation curable monomer component or oligomer component, an amount allowing the adhesive strength of the pressure-sensitive adhesive layer to be reduced can be appropriately determined according to the type of the pressure-sensitive adhesive layer. Generally, the blending amount is, for example, 5 to 500 parts by weight, preferably about 40 to 150 parts by weight, based on 100 parts by weight of a base polymer such as an acryl-based polymer forming the pressure-sensitive adhesive.

Examples of the radiation curing-type pressure-sensitive adhesive include, besides the addition-type radiation curing-type pressure-sensitive adhesive described previously, an intrinsic radiation curing-type pressure-sensitive adhesive using, as a base polymer, a polymer having a carbon-carbon double bond in the polymer side chain or main chain or at the end of the main chain. The intrinsic radiation curing-type pressure-sensitive adhesive is preferable because it is not required to contain, or mostly does not contain an oligomer component or the like which is a low-molecular component, and therefore the oligomer component or the like does not migrate in the pressure-sensitive adhesive over time, so that a pressure-sensitive adhesive layer having a stable layer structure can be formed.

For the base polymer having a carbon-carbon double bond, one having a carbon-carbon double bond and also an adherability can be used without no particular limitation. Such a base polymer is preferably one having an acryl-based polymer as a basic backbone. Examples of the basic backbone of the acryl-based polymer include the acryl-based polymers described previously as an example.

The method for introducing a carbon-carbon double bond into the acryl-based polymer is not particularly limited, and various methods can be employed, but it is easy in molecular design to introduce the carbon-carbon double bond into a polymer side chain. Mention is made to, for example, a method in which a monomer having a functional group is copolymerized into an acryl-based polymer beforehand, and thereafter a compound having a functional group that can react with the above-mentioned functional group, and a carbon-carbon double bond is subjected to a condensation or addition reaction while maintaining the radiation curability of the carbon-carbon double bond.

Examples of the combination of these functional groups include a combination of a carboxylic acid group and an epoxy group, a combination of a carboxylic acid group and an aziridyl group and a combination of a hydroxyl group and an isocyanate group. Among these combinations of functional groups, the combination of a hydroxyl group and an isocyanate group is suitable in terms of ease of reaction tracing. The functional group may be present at the side of any of the acryl-based polymer and the aforementioned compound as long as the combination of the functional groups is such a combination that the acryl-based polymer having a carbon-carbon double bond is generated, but for the preferable combination, it is preferred that the acryl-based polymer have a hydroxyl group and the aforementioned compound have an isocyanate group. In this case, examples of the isocyanate compound having a carbon-carbon double bond include metacryloyl isocyanate, 2-metacryloyloxyethyl isocyanate, m-isopropenyl-α,α-dimethylbenzyl isocyanate. As the acryl-based polymer, one obtained by copolymerizing the hydroxy group-containing monomers described previously as an example, ether-based compounds such as 2-hydroxyethylvinyl ether, 4-hydroxybutyl vinyl ether and diethylene glycol monovinyl ether, and so on may be used.

For the intrinsic radiation curing-type pressure-sensitive adhesive, the base polymer (particularly acryl-based polymer) having a carbon-carbon double bond can be used alone, but the radiation curable monomer component or oligomer component within the bounds of not deteriorating properties can also be blended. The amount of the radiation curable oligomer component or the like is normally within a range of 30 parts by weight or less, preferably in a range of 0 to 10 parts by weight, based on 100 parts by weight of the base polymer.

A photopolymerization initiator is preferably included in the radiation curing-type pressure-sensitive adhesive when it is cured by ultraviolet rays or the like. Examples of the photopolymerization initiator include α-ketol-based compounds such as 4-(2-hydroxyethoxy)phenyl(2-hydroxy-2-propyl)ketone, α-hydroxy-α,α′-dimethylacetophenone, 2-methyl-2-hydroxypropiophenone and 1-hydroxycyclohexyl phenyl ketone; acetophenone-based compounds such as methoxyacetophenone, 2,2-dimethoxy-2-phenylacetophenone, 2,2-diethoxyacetophenone, and 2-methyl-1-[4-(methylthio)-phenyl]-2-morphorinopropane-1; benzoin ether-based compounds such as benzoin ethyl ether, benzoin isopropyl ether and anisoin methyl ether; ketal-based compounds such as benzyldimethylketal; aromatic sulfonyl chloride-based compounds such as 2-naphthalenesulfonyl chloride; photoactive oxime-based compounds such as 1-phenon-1,1-propanedione-2-(o-ethoxycarbonyl)oxime; benzophenone-based compounds such as benzophenone, benzoyl benzoic acid and 3,3′-dimethyl-4-methoxybenzophenone; thioxanthone-based compounds such as thioxanthone, 2-chlorothioxanthone, 2-methylthioxanthone, 2,4-dimethylthioxanthone, isopropylthioxanthone, 2,4-dichlorothioxanthone, 2,4-diethylthioxanthone and 2,4-diisopropylthioxanthone; camphorquinone; halogenated ketone; acylphosphinoxide; and acylphosphonate. The blending amount of the photopolymerization initiator is, for example, about 0.05 to 20 parts by weight based on 100 parts by weight of the base polymer such as an acryl-based polymer which forms a pressure-sensitive adhesive.

When curing hindrance by oxygen occurs at the time of the irradiation, it is desirable to block oxygen (air) from the surface of the radiation curing-type pressure-sensitive adhesive layer 1b by some method. Examples include a method in which the surface of the pressure-sensitive adhesive layer 1b is covered with a separator, and a method in which irradiation by ultraviolet rays or the like is carried out in a nitrogen gas atmosphere.

The pressure-sensitive adhesive layer 1b may contain various kinds of additives (e.g. colorant, thickener, bulking agent, filler, tackifier, plasticizer, antiaging agent, antioxidant, surfactant, crosslinker, etc.).

The thickness of the pressure-sensitive adhesive layer 1b is not particularly limited, but is preferably about 1 to 50 μm from the viewpoint of compatibility of prevention of chipping of a chip cut surface, fixation and retention of a thermosetting resin composition 2, and so on. The thickness is preferably 2 to 30 μm, more preferably 5 to 25 μm.

(Method for Producing Sealing Sheet)

The sealing sheet 10 according to this embodiment can be prepared by, for example, preparing the back surface grinding tape 1 and the thermosetting resin composition 2 separately in advance, and finally bonding the former and the latter together. Specifically, the sealing sheet 10 can be prepared in accordance with the following procedure.

First, the base material 1a can be film formed by a previously known film formation method. Examples of the method for a film formation may include a calender film formation method, a casting method in an organic solvent, an inflation extrusion method in a closed system, a T-die extrusion method, a co-extrusion method and a dry lamination method.

Next, a pressure-sensitive adhesive composition for formation of a pressure-sensitive adhesive layer is prepared. Resins and additives as described for the pressure-sensitive adhesive layer, and so on are blended in the pressure-sensitive adhesive composition. The prepared pressure-sensitive adhesive composition is applied onto the base material 1a to form a coating film, and the coating film is then dried (crosslinked by heating as necessary) under predetermined conditions to form the pressure-sensitive adhesive layer 1b. The coating method is not particularly limited, and examples thereof include roll coating, screen coating and gravure coating. For drying conditions, for example, the drying temperature is in a range of 80 to 150° C., and the drying time is in a range of 0.5 to 5 minutes. The pressure-sensitive adhesive layer 1b may be formed by applying a pressure-sensitive adhesive composition onto a separator to form a coating film, followed by drying the coating film under the aforementioned conditions. Thereafter, the pressure-sensitive adhesive layer 1b is bonded onto the base material 1a together with the separator. In this way, the back surface grinding tape 1 including the base material 1a and the pressure-sensitive adhesive layer 1b is prepared.

The sheet-like thermosetting resin composition 2 is prepared, for example, as follows. First, an epoxy resin and a specific phenol resin which are formation materials for the thermosetting resin composition 2 are appropriately dissolved or dispersed in a solvent (for example, methyl ethyl ketone or ethyl acetate) to prepare a coating liquid. A thermoplastic component and various additives or the like are blended with the coating liquid if necessary.

Next, the prepared coating liquid is coated on a substrate separator so as to form a coating film having a predetermined thickness. The coating film is then dried under predetermined conditions, so that the sheet-like thermosetting resin composition is formed. The coating method is not particularly limited, and examples thereof include roll coating, screen coating and gravure coating. For drying conditions, for example, the drying temperature is in a range of 70 to 160° C., and the drying time is in a range of 1 to 5 minutes. The coating liquid may be coated on the separator to form the coating film, followed by drying the coating film under the dry conditions to form the sheet-like thermosetting resin composition. Then, the thermosetting resin composition and the separator are bonded to the substrate separator.

Subsequently, the separator is peeled off from each of the back surface grinding tape 1 and the thermosetting resin composition 2, and the tape and the thermosetting resin composition are bonded together such that the thermosetting resin composition and the pressure-sensitive adhesive layer form a bonding surface. Bonding can be performed by, for example, heat pressure-bonding. At this time, the lamination temperature is not particularly limited and is, for example, preferably 30 to 50° C., more preferably 35 to 45° C. The linear pressure is not particularly limited and is, for example, preferably 0.98 to 196 N/cm, more preferably 9.8 to 98 N/cm. Next, the base material separator on the thermosetting resin composition is peeled off to obtain a sealing sheet according to this embodiment.

<Method for Producing a Semiconductor Device>

Next, one embodiment of a method for producing a semiconductor device using the sealing sheet will be described. The method for producing a semiconductor device according to the present embodiment includes: a fixing step of fixing a semiconductor element to an adherend with the thermosetting resin composition interposed therebetween; and a curing step of curing the thermosetting resin composition. However, in the present embodiment, the thermosetting resin composition is stacked on a back surface grinding tape to form the sealing sheet. The adherend and the semiconductor element are electrically connected to each other when the semiconductor element is fixed. Therefore, in more detail, the method for producing a semiconductor device of the present embodiment includes: a bonding step of bonding the thermosetting resin composition of the sealing sheet to a circuit surface of a semiconductor wafer on which a connection member is formed; a grinding step of grinding the back surface of the semiconductor wafer; a wafer fixing step of peeling the semiconductor wafer together with the thermosetting resin composition from the back surface grinding tape to bond the semiconductor wafer to a dicing tape; a dicing step of dicing the semiconductor wafer to form a semiconductor element with the thermosetting resin composition; a pickup step of peeling the semiconductor element with the thermosetting resin composition from the dicing tape; a connection step of electrically connecting the semiconductor element and the adherend through the connection member while filling a space between the adherend and the semiconductor element with the thermosetting resin composition; and a curing step of curing the thermosetting resin composition.

[Bonding Step]

In the bonding step, a circuit surface 3a of the semiconductor wafer 3, on which the connection member 4 is formed, and the thermosetting resin composition 2 of the sealing sheet 10 are bonded (see FIG. 2A).

(Semiconductor Wafer)

A plurality of connection members 4 are formed on the circuit surface 3a of the semiconductor wafer 3 (see FIG. 2A). The material of the connection member such as a bump or an electrically conductive material is not particularly limited, and examples thereof include solders (alloys) such as a tin-lead-based metal material, a tin-silver-based metal material, a tin-silver-copper-based metal material, a tin-zinc-based metal material, a tin-zinc-bismuth-based metal material, a gold-based metal material and a copper-based metal material. The height of the connection member is also determined according to an application, and is generally about 15 to 100 μm. Of course, the heights of individual connection members in the semiconductor wafer 3 may be the same or different.

In the method for producing a semiconductor device according to this embodiment, as the thickness of the thermosetting resin composition, the height X (μm) of the connection member formed on the surface of the semiconductor wafer and the thickness Y (μm) of the thermosetting resin composition preferably satisfies the following relationship:

0.5≦Y/X≦2

The height X (μm) of the connection member and the thickness Y (μm) of the cured film satisfy the above relationship, whereby a space between the semiconductor element and the adherend can be sufficiently filled, and excessive protrusion of the thermosetting resin composition from the space can be prevented, so that contamination of the semiconductor element by the thermosetting resin composition, and so on can be prevented. When the heights of the respective connection members are different, the height of the highest connection member is used as the reference.

(Bonding)

As shown in FIG. 2A, first a separator that is optionally provided on the under-fill 2 of the sealing sheet 10 is appropriately peeled off, the circuit surface 3a of the semiconductor wafer 3, on which the connection member 4 is formed, and the thermosetting resin composition 2 are made to face to each other, and the thermosetting resin composition 2 and the semiconductor wafer 3 are bonded together (mount).

The method for bonding is not particularly limited, but is preferably a method by pressure-bonding. Pressure-bonding is normally performed by pressing with a pressure of preferably 0.1 to 1 MPa, more preferably 0.3 to 0.7 MPa by known pressing means such as a pressure roller. At this time, pressure-bonding may be carried out while heating to about 40 to 100° C. It is also preferable to carry out pressure-bonding under a reduced pressure (1 to 1000 Pa) for improving adhesion.

[Grinding Step]

In the grinding step, a surface 3b opposite to the circuit surface 3a of the semiconductor wafer 3 (i.e. back surface) is ground (see FIG. 2B). A processor for thinning that is used for grinding the back surface of the semiconductor wafer 3 is not particularly limited, and examples thereof may include a grinding machine (back grinder) and a polishing pad. Back surface grinding may be carried out by a chemical process such as etching. Back surface grinding is carried out until the semiconductor wafer has a desired thickness (e.g. 700 to 25 μm).

[Wafer Fixing Step]

After the grinding step, the semiconductor wafer 3 is peeled from the back surface grinding tape 1 in a state where the thermosetting resin composition 2 is bonded to the semiconductor wafer 3, and the semiconductor wafer 3 is bonded to the dicing tape 11 (see FIG. 2C). In this case, the semiconductor wafer 3 and the dicing tape 11 are bonded so that the back surface 3b of the semiconductor wafer 3 and the pressure-sensitive adhesive layer 11b of the dicing tape 11 face each other. Therefore, the thermosetting resin composition 2 bonded onto the circuit surface 3a of the semiconductor wafer 3 is in an exposed state. The dicing tape 11 has a structure where the pressure-sensitive adhesive layer 11b is stacked on the base material 11a. The base material 11a and the pressure-sensitive adhesive layer 11b can be suitably prepared using the components and processes shown in the items of the base material 1a and the pressure-sensitive adhesive layer 1b of the back surface grinding tape 1. A commercially available dicing tape can also be suitably used.

When the semiconductor wafer 3 is peeled from the back surface grinding tape 1 and the pressure-sensitive adhesive layer 1b has radiation curability, the pressure-sensitive adhesive layer 1b is irradiated with radiation to cure the pressure-sensitive adhesive layer 1b, so that easy peeling can be performed. The irradiation amount of the radiation may be appropriately set in view of the kind of radiation to be used and the curing degree of the pressure-sensitive adhesive layer, or the like.

[Dicing Step]

In the dicing step, as shown in FIG. 2D, the semiconductor wafer 3 and the thermosetting resin composition 2 are diced based on the dicing position determined by direct light, indirect light, infrared rays, etc. to form a diced semiconductor element 5 with the thermosetting resin composition. By appropriately adjusting the transparency of the thermosetting resin composition 2 according to the average particle diameter of the inorganic filler etc., the dicing position can be easily determined. Through the dicing step, the semiconductor wafer 3 is cut to a predetermined size and thereby formed into individual pieces (small pieces) to produce a semiconductor chip (semiconductor element) 5. The semiconductor chip 5 thus obtained is integrated with the thermosetting resin composition 2 cut in the same shape. The dicing is performed from the circuit surface 3a of the semiconductor wafer 3 onto which the thermosetting resin composition 2 is bonded according to a standard method.

In this step, for example, a cutting method called full cut, in which cutting is made to the dicing tape 11, can be employed. The dicing device used in this step is not particularly limited, and one that is previously known can be used. The semiconductor wafer is adhesively fixed with excellent adhesion by the dicing tape 11, so that chipping and chip fly can be suppressed, and also damage of the semiconductor wafer can be suppressed. When the thermosetting resin composition is formed from a resin composition containing an epoxy resin, occurrence of glue protrusion of the thermosetting resin composition at the cut surface can be suppressed or prevented even though the thermosetting resin composition is cut by dicing. As a result, reattachment of cut surfaces (blocking) can be suppressed or prevented, so that pickup described later can be further satisfactorily performed.

When expanding of the dicing tape is carried out subsequently to the dicing step, the expanding can be carried out using a previously known expanding device. The expanding device has a doughnut-like outer ring capable of pushing down the dicing tape via a dicing ring, and an inner ring having a diameter smaller than that of the outer ring and supporting the dicing tape. Owing to the expanding step, adjacent semiconductor chips can be prevented from contacting with each other and being damaged in a pickup step described later.

[Pickup Step]

As shown in FIG. 2E, pickup of the semiconductor chip 5 with the thermosetting resin composition 2 is carried out to peel off a laminate A of the semiconductor chip 5 and the thermosetting resin composition 3 from the dicing tape 11 for collecting the semiconductor chip 5 adhesively fixed on the dicing tape 11.

The method for pickup is not particularly limited, and previously known various methods can be employed. Mention is made of, for example, a method in which individual semiconductor chips are pushed up by a needle from the base material side of the dicing tape, and the semiconductor chips, which have been pushed up, are collected by a pickup device. The semiconductor chip 5, which has been picked up, is integrated with the thermosetting resin composition 2 bonded to the circuit surface 3a to form the laminate A.

Here, pickup is performed after irradiating the pressure-sensitive adhesive layer 11b with ultraviolet rays when the pressure-sensitive adhesive layer 11b of the dicing tape 11 is of an ultraviolet-ray curing-type. Consequently, adhesive power of the pressure-sensitive adhesive layer 11b to the semiconductor chip 5 decreases, so that it becomes easy to peel off the semiconductor chip 5. As a result, pickup can be performed without damaging the semiconductor chip 5. Conditions such as an irradiation intensity and an irradiation time for irradiation of ultraviolet rays are not particularly limited, and may be appropriately set as necessary. As alight source used for irradiation of ultraviolet rays, for example, a low-pressure mercury lamp, a low-pressure high-power lamp, a medium-pressure mercury lamp, an electrodeless mercury lamp, a xenon flash lamp, an excimer lamp, an ultraviolet LED or the like can be used.

[Mounting Step]

In the mounting step, the mounting position of the semiconductor element 5 is determined in advance by direct light, indirect light, infrared rays, etc. The semiconductor element 5 and an adherend 16 are electrically connected through the connection member 4 while filling a space between the adherend 16 and the semiconductor element 5 with the thermosetting resin composition 2 according to the determined mounting position (see FIG. 2F). By appropriately adjusting the transparency of the thermosetting resin composition 2 according to the average particle diameter of the inorganic filler etc., the mounting position can be easily determined. Specifically, the semiconductor chip 5 of the laminate A is fixed to the adherend 16 in accordance with a usual method in such a form that the circuit surface 3a of the semiconductor chip 5 is made to face to the adherend 16. For example, the bump (connection member) 4 formed on the semiconductor chip 5 is contacted with an electrically conductive material 17 (solder or the like) for bonding, which is attached to the connection pad of the adherend 16, and the electrically conductive material is melted while pressing, whereby electrical connection between the semiconductor chip 5 and the adherend 16 can be provided to fix the semiconductor chip 5 to the adherend 16. Since the thermosetting resin composition 2 is bonded to the circuit surface 3a of the semiconductor chip 5, a space between the semiconductor chip 5 and the adherend 16 is filled with the thermosetting resin composition 2 concurrently with electrically connecting of the semiconductor chip 5 and the adherend 16.

Generally, in the mounting process, the temperature is 100 to 300° C. as a heating condition, and the pressure is 0.5 to 500 N as a pressing condition. A heat pressure-bonding treatment in the mounting process may be carried out in a multiple stage. For example, such a procedure can be employed that a treatment is carried out at 150° C. and 100 N for 10 seconds, followed by carrying out a treatment at 300° C. and 100 to 200 N for 10 seconds. By carrying out the heat pressure-bonding treatment in a multiple stage, a resin between the connection member and the pad can be efficiently removed to obtain a better metal-metal joint.

As the adherend 16, a lead frame, various kinds of substrates such as and a circuit substrate (such as a wiring circuit substrate), and other semiconductor elements can be used. Examples of the material of the substrate include, but are not limited to, a ceramic substrate and a plastic substrate. Examples of the plastic substrate include an epoxy substrate, a bismaleimide triazine substrate, a polyimide substrate and a glass epoxy substrate.

In the mounting process, one or both of the connection member and the electrically conductive material are melted to connect the bump 4 of the connection member forming surface 3a of the semiconductor chip 5, and the electrically conductive material 17 on the surface of the adherend 16, and the temperature at which the bump 4 and the electrically conductive material 17 are melted is normally about 260° C. (for example 250° C. to 300° C.). The sealing sheet according to this embodiment can be made to have a such a heat resistance that it can endure a high temperature in the mounting process, by forming the thermosetting resin composition 2 from an epoxy resin or the like.

[Curing Step of Thermosetting Resin Composition]

After the semiconductor element 5 and the adherend 16 are electrically connected, the thermosetting resin composition 2 is cured by heating. This makes it possible to protect the surface of the semiconductor element 5, and also to seal the space between the semiconductor element 5 and the adherend 16 so that the connection reliability of the semiconductor device can be secured. The heating temperature for curing the thermosetting resin composition is not particularly limited, and may be 150 to 200° C. for 10 to 120 minutes. When the thermosetting resin composition is cured by the heat treatment in the mounting step, this curing step can be omitted.

[Post-Sealing Step]

Next, a post-sealing step may be carried out for protecting the whole of a semiconductor device 20 including the mounted semiconductor chip 5. The post-sealing step is carried out using a sealing resin. The sealing conditions at this time are not particularly limited, and normally the sealing resin is heat-cured by heating at 175° C. for 60 seconds to 90 seconds, but the present invention is not limited thereto and, for example, the sealing resin may be cured at 165° C. to 185° C. for several minutes.

The sealing resin is not particularly limited as long as it is a resin having an insulating property (insulating resin), and can be selected from sealing materials such as known sealing resins and used, but an insulating resin having elasticity is more preferable. Examples of the sealing resin include a resin composition containing an epoxy resin. Examples of the epoxy resin include the epoxy resins described previously as an example. The sealing resin by the resin composition containing an epoxy resin may contain, as a resin component, a thermosetting resin (phenol resin, etc.), a thermoplastic resin and so on in addition to an epoxy resin. The phenol resin can also be used as a curing agent for the epoxy resin, and examples of such a phenol resin include the phenol resins described previously as an example.

[Semiconductor Device]

A semiconductor device obtained using the sealing sheet will now be described with reference to the drawings (see FIG. 2F). In the semiconductor device 20 according to this embodiment, the semiconductor element 5 and the adherend 16 are electrically connected through the bump (connection member) 4 formed on the semiconductor element 5 and the electrically conductive material 17 provided on the adherend 16. The thermosetting resin composition 2 is placed between the semiconductor element 5 and the adherend 16 so as to fill a space therebetween. Since the semiconductor device 20 is obtained by the production method employing the predetermined thermosetting resin composition 2, the surface protection of the semiconductor element 5, the filling of the space between the semiconductor element 5 and the adherend 16, and the electrical connection between the semiconductor device 5 and the adherend 16 are provided at a sufficient level, so that the semiconductor device 20 can exhibit high reliability.

### Second Embodiment

A semiconductor wafer with a circuit formed on one surface is used in the first embodiment, whereas in this embodiment, a semiconductor device is produced using a semiconductor wafer with circuits formed on both surfaces. Since the semiconductor wafer used in this embodiment has an intended thickness, a grinding step is omitted. Thus, as a sealing sheet in the second embodiment, a sealing sheet including a dicing tape and a thermosetting resin composition laminated on the dicing tape is used. Typical steps in the second embodiment include a providing step of providing the sealing sheet, a bonding step of bonding together a semiconductor wafer, in which circuit surfaces each having a connection member are formed on both surfaces thereof, and the thermosetting resin composition of the sealing sheet, a dicing step of dicing the semiconductor wafer to form a semiconductor element with the thermosetting resin composition, and a pickup step of peeling off the semiconductor element with the thermosetting resin composition from the sealing sheet. Thereafter, the mounting step and the subsequent steps are carried out to produce a semiconductor device.

[Providing Step]

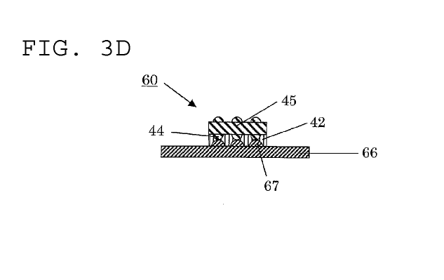

In the providing step, a sealing sheet including a dicing tape 41 and a thermosetting resin composition 42 laminated on the dicing tape 41 is provided (see FIG. 3A). The dicing tape 41 includes a base material 41a and a pressure-sensitive adhesive layer 41b laminated on the base material 41a. The thermosetting resin composition 42 is laminated on the pressure-sensitive adhesive layer 41b. The base material 41a and the pressure-sensitive adhesive layer 41b of the dicing tape 41 and the thermosetting resin composition 42, which are same as those in the first embodiment, can be used.

[Bonding Step]

In the bonding step, as shown in FIG. 3A, a semiconductor wafer 43, in which circuit surfaces each having a connection member 44 are formed on both surfaces thereof, and the thermosetting resin composition 42 of the sealing sheet are bonded together. Since the strength of a semiconductor wafer thinned to a predetermined thickness is low, the semiconductor wafer may be fixed to a support such as support glass with a temporary fixing material interposed therebetween for the purpose of reinforcement in some cases (not shown). In this case, a step of peeling off the support together with the temporary fixing material may be included after bonding the semiconductor wafer and the thermosetting resin composition together. Which circuit surfaces of the semiconductor wafer 43 is bonded to the thermosetting resin composition 42 may be changed according to the intended structure of the semiconductor device.

The semiconductor wafer 43 is same as the semiconductor wafer in the first embodiment except that circuit surfaces each having the connection member 44 are formed on both surfaces, and the semiconductor wafer 43 has a predetermined thickness. Connection members 44 on both surfaces of the semiconductor wafer 43 may or may not be electrically connected. For electrical connection of connection members 44, mention is made for connection provided through a via called a TSV type. For bonding conditions, the bonding conditions in the first embodiment can be suitably employed.

[Dicing Step]

In the dicing step, the semiconductor wafer 43 and the thermosetting resin composition 42 are diced to form a semiconductor element 45 with the thermosetting resin composition (see FIG. 3B). For dicing conditions, the conditions in the first embodiment can be suitably employed. Since dicing is conducted on the exposed circuit surface of the semiconductor wafer 43, a dicing position is easily detected.

[Pickup Step]

In the pickup step, the semiconductor element 45 with the thermosetting resin composition 42 is peeled off from the dicing tape 41 (FIG. 3C). For pickup conditions, the pickup conditions in the first embodiment can be suitably employed.

[Mounting Process]

In the mounting process, the semiconductor element 45 and the adherend 66 are electrically connected through the connection member 44 while filling a space between the adherend 66 and the semiconductor element 45 using the thermosetting resin composition (see FIG. 3D). For conditions in the mounting process, the conditions in the first embodiment can be suitably employed. Consequently, a semiconductor device 60 according to this embodiment can be produced.

Subsequently, as in the first embodiment, a thermosetting resin composition curing step and a sealing step may be carried out as necessary.

### Third Embodiment

In the first embodiment, a back surface grinding tape is used as a constituent member of a sealing sheet, whereas in this embodiment, a pressure-sensitive adhesive layer of the back surface grinding tape is not provided, and a base material alone is used. Thus, a sealing sheet of this embodiment is in such a state that a thermosetting resin composition is laminated on a base material. In this embodiment, a grinding step can be optionally carried out, but irradiation of ultraviolet rays before a pickup step is not carried out because a pressure-sensitive adhesive layer is omitted. Except for these aspects, a predetermined semiconductor device can be produced through steps same as those in the first embodiment.

### EXAMPLES

Preferred Examples of the present invention will be illustratively described in detail below. However, for the materials, the blending amounts, and so on described in Examples, the scope of the present invention is not intended to be limited thereto unless definitely specified. Further, the “part (s)” refer to part (s) by weight.

### Examples 1 to 4 and Comparative Examples 1 to 4

### Preparation of Sealing Sheet

The following components were dissolved in methyl ethyl ketone at a ratio shown in Table 1 to prepare an adhesive composition solution having a solid concentration of 23.6 to 60.6% by weight.

Elastomer 1: acrylic acid ester-based polymer having an ethyl acrylate-methyl methacrylate as a main component (trade name “Paraclone W-197CM” manufactured by Negami Chemical Industrial Co., Ltd.)

Elastomer 2: acrylic acid ester-based polymer having a butyl acrylate-acrylonitrile as a main component (trade name “SG-28GM” manufactured by Nagase chemteX Corporation)

Epoxy resin 1: trade name “Epicoat 828” manufactured by JER Corporation

Epoxy resin 2: trade name “Epicoat 1004” manufactured by JER Corporation

Phenol Resin 1: trade name “MEH-7851M” manufactured by Meiwa Plastic Industries, Ltd.

Phenol Resin 2: trade name “MEH-7851-3H” manufactured by Meiwa Plastic Industries, Ltd.

Phenol Resin 3: trade name “P-200” manufactured by Arakawa Chemical Industries, Ltd.

Phenol Resin 4: trade name “DPP-M” manufactured by Nippon Oil Co., Ltd.

Inorganic Filler 1: Spherical Silica (trade name “YC100C-MLC” manufactured by Admatechs)

Inorganic Filler 2: spherical silica (trade name “SO-25R” manufactured by Admatechs)

Organic acid: o-anisic acid (trade name “Orthoanisic Acid” manufactured by Tokyo Chemical Industry Co., Ltd.)

Curing agent: Imidazole catalyst (trade name “2PHZ-PW” manufactured by Shikoku Chemicals Corporation)

The adhesive composition solution was applied onto a release-treated film made of a silicone release-treated polyethylene terephthalate film having a thickness of 50 μm as a release liner (separator), and thereafter dried at 130° C. for 2 minutes to thereby prepare a thermosetting resin composition having a thickness of 45 μm.

The thermosetting resin composition was bonded onto a pressure-sensitive adhesive layer of a back grind tape (trade name “UB-2154” manufactured by Nitta Denko Corporation) using a hand roller to prepare a sealing sheet.

(Measurement of Thermal Expansion Coefficient α)

After the prepared thermosetting resin composition was subjected to a heat-curing treatment at 175° C. for 1 hour, a thermal expansion coefficient α was measured using a thermomechanical measurement apparatus (Model: Q-400EM manufactured by TA Instruments). Specifically, a sample was made to have a size of 15 mm (length)×5 mm (width)×200 μm (thickness), the measurement sample was set in a tool for film tensile measurement in the apparatus, and then placed under conditions of tensile load: 2 g and temperature rising rate: 10° C./min in a temperature zone of from −50 to 300° C., and a thermal expansion coefficient α was calculated from expansion rate at 20° C. to 60° C. The results are shown in Table 1.

(Measurement of Storage Elastic Modulus E′)

First the prepared thermosetting resin composition was subjected to a heat-curing treatment at 175° C. for 1 hour, and then a storage elastic modulus was measured using a solid viscoelasticity measurement apparatus (Model: RSA III manufactured by Rheometric Scientific Co., Ltd.). Specifically, a sample was made to have a size of 40 mm (length)×10 mm (width)×200 μm (thickness), the measurement sample was set in a tool for film tensile measurement, a tensile storage elastic modulus and loss elastic modulus in a temperature zone of from −50 to 300° C. were measured under conditions of frequency: 1 Hz and temperature rising rate: 10° C./min, and a storage elastic modulus (E′) at 25° C. was read. The results are shown in Table 1.

(Measurement of Glass Transition Temperature)

The method for measuring a glass transition temperature of a thermosetting resin composition is as follows. A thermosetting resin composition was first heat-cured by a heating treatment at 175° C. for 1 hour, and then cutout using a cutter knife into a strip having a thickness of 200 μm, a length of 40 mm (measurement length) and width of 10 mm, and a storage elastic modulus and a loss elastic modulus at −50 to 300° C. were measured using a solid viscoelasticity measurement apparatus (RSA III manufactured by Rheometric Scientific Co., Ltd.). For measurement conditions, the frequency was 1 Hz and the temperature rising rate was 10° C./min. Further, a value of tan δ (G″ (loss elastic modulus)/G′ (storage elastic modulus)) was calculated to thereby obtain a glass transition temperature. The results are shown in table 1.

(Preparation of Semiconductor Device)

A silicon wafer with a bump on one surface, in which a bump was formed on one surface, was provided, and the prepared sealing sheet was bonded to a surface on which the bump of the silicon wafer with a bump on one surface was formed with the thermosetting resin composition as a bonding surface. As the silicon wafer with a bump on one surface, the following article was used. Bonding conditions are as follows. The ratio of the thickness Y (=45 μm) of the thermosetting resin composition to the height X (=45 μm) of a connection member (Y/X) was 1.

<Silicon Wafer with a Bump on One Surface>

Diameter of silicon wafer: 8 inches

Thickness of silicon wafer: 0.7 mm (700 μm)

Height of bump: 45 μm

Pitch of bump: 50 μm

Material of bump: solder

<Bonding Conditions>

Bonding device: trade name “DSA 840-WS” manufactured by NITTO SEIKI CO., Ltd.

Bonding speed: 5 mm/min

Bonding pressure: 0.25 MPa

Stage temperature at the time of bonding: 80° C.

Degree of vacuum at the time of bonding: 150 Pa

A silicon wafer with bumps on one surface and a sealing sheet were bonded together in accordance with the procedure described above, followed by grinding the back surface of the silicon wafer under the following conditions.

<Grinding Condition>

Grinding apparatus: trade name “DFG-8560” manufactured by DISCO Corporation

Semiconductor wafer: back surface ground from a thickness of 0.7 mm (700 μm) to 0.2 mm (200 μm)

The silicon wafer and the thermosetting resin composition were peeled from the back grind tape after the back surface was ground. The silicon wafer was bonded onto the pressure-sensitive adhesive layer of a dicing tape (DU-300 manufactured by Nitto Denko Corporation), and fixed. At this time, the back surface of the silicon wafer was bonded to the pressure-sensitive adhesive layer, and the thermosetting resin composition bonded onto the circuit surface of the silicon wafer was exposed.

Next, the semiconductor wafer was diced under the following conditions. Dicing was performed by full cut so as to have a chip size of 7.3 mm×7.3 mm.

<Dicing Conditions>

Dicing device: trade name “DFD-6361” manufactured by DISCO Corporation

Dicing ring: “2-8-1” (manufactured by DISCO Corporation)

Dicing speed: 30 mm/sec

Dicing blade:
Z1; “203O-SE 27HCDD” manufactured by DISCO Corporation
Z2; “203O-SE 27HCBB” manufactured by DISCO Corporation

Dicing blade rotation number:
Z1; 40000 rpm
Z2; 45000 rpm

Cut mode: step cut

Wafer chip size: 7.3 mm×7.3 mm

Next, a laminate of a thermosetting resin composition and a semiconductor chip with a bump on one surface was picked up by a method of push-up by a needle from the base material side of each sealing sheet. Pickup conditions are as follows.

<Pickup Conditions>

Pickup device: trade name “SPA-300” manufactured by SHINKAWA LTD.

The number of needles: 9

Needle push-up amount: 500 μm (0.5 mm)

Needle push-up speed: 20 mm/second

Pickup time: 1 second

Expanding amount: 3 mm

Finally, the semiconductor chip was mounted by heat pressure-bonding the semiconductor chip to a BGA substrate under the following heat pressure-bonding conditions in the state that the bump forming surface of the semiconductor chip and the BGA substrate are made to face to each other. Consequently, a semiconductor device with a semiconductor chip mounted on a BGA substrate was obtained. In this step, a two-stage process of performing heat pressure-bonding under the heat pressure-bonding condition 1 and then under the heat pressure-bonding condition 2 was carried out.

<Heat Pressure-Bonding Condition 1>

Pickup device: trade name “FCB-3” manufactured by Panasonic Corporation

Heating temperature: 150° C.

Load: 98 N

Retention time: 10 seconds

<Heat Pressure-Bonding Condition 2>

Pickup device: trade name “FCB-3” manufactured by Panasonic Corporation

Heating temperature: 260° C.

Load: 98 N

Retention time: 10 seconds

(Evaluation of Reliability of Semiconductor Device)

10 samples were prepared for each of semiconductor devices of Examples and Comparative Examples, a heat cycle with one cycle of from −55° C. to 125° C. for 30 minutes was repeated 500 cycles, and the semiconductor device was then embedded by an embedding epoxy resin. Then, the semiconductor device was cut in a direction perpendicular to a substrate such that a solder joint was exposed, and the cross section of the exposed solder joint was polished. Thereafter, the polished cross section of the solder joint was observed with an optical microscope (magnification: 1000×), and for each evaluation, “∘” was assigned when the solder joint was not broken and “x” was assigned when one or more samples had a broken solder joint. The results are shown in Table 1.

TABLE 1

| | | | | | | Comparative | Comparative | Comparative | Comparative |
|---|---|---|---|---|---|---|---|---|---|
| | | Example 1 | Example 2 | Example 3 | Example 4 | Example 1 | Example 2 | Example 3 | Example 4 |
| Composition | Elastomer 1 | 10 | 10 | — | — | 10 | 10 | — | 10 |
| | Elastomer 2 | — | — | 10 | 10 | — | — | 10 | — |
| | Epoxy resin 1 | 10 | 10 | 10 | 10 | 10 | 10 | 10 | 10 |
| | Epoxy resin 2 | 10 | 10 | 10 | 10 | 10 | 10 | 10 | 10 |
| | Phenol resin 1 | 21 | — | — | 21 | — | — | — | — |
| | Phenol resin 2 | — | 23 | 23 | — | — | — | — | — |
| | Phenol resin 3 | — | — | — | — | 10 | — | 10 | — |
| | Phenol resin 4 | — | — | — | — | — | 17 | — | 17 |
| | Inorganic filler 1 | 68 | 68 | 90 | — | 68 | 68 | 90 | — |
| | Inorganic filler 2 | — | — | — | 68 | — | — | — | 68 |
| | Organic acid | 2.7 | 2.7 | 2.7 | 2.7 | 2.7 | 2.7 | 2.7 | 2.7 |
| | Curing agent | 0.15 | 0.15 | 0.15 | 0.15 | 0.15 | 0.15 | 0.15 | 0.15 |
| | Hydroxyl equivalent of | 214 | 223 | 223 | 214 | 105 | 170 | 105 | 105 |
| | phenol resin [g/eq] | | | | | | | | |
| Evaluation | Thermal expansion | 48 | 47 | 37 | 40 | 43 | 45 | 36 | 40 |
| | coefficient α [ppm/K] | | | | | | | | |
| | Storage elastic | 2500 | 2600 | 4300 | 3000 | 4300 | 3800 | 5300 | 4800 |
| | modulus E′ [MPa] | | | | | | | | |
| | Glass transition | 126 | 138 | 134 | 128 | 140 | 139 | 139 | 139 |
| | temperature Tg (° C.) | | | | | | | | |
| | Reliability test, the number of | 10/10 | 10/10 | 10/10 | 10/10 | 0/10 | 3/10 | 0/10 | 0/10 |
| | good products | | | | | | | | |
| | Determination | ◯ | ◯ | ◯ | ◯ | X | X | X | X |

* In the table, the unit of the value for each component is part(s) by weight.

As can be seen from Table 1, occurrence of fracture of the solder joint was suppressed in the semiconductor devices of Examples 1 to 4. On the other hand, the solder joint was fractured in the semiconductor devices of Comparative Examples 1 to 4. Thus, it is found that a highly-reliable semiconductor device in which the fracture of the solder joint is suppressed can be produced by using a thermosetting resin composition containing an epoxy resin and a novolak-type phenol resin having a hydroxyl equivalent of 200 g/eq or more.

### DESCRIPTION OF REFERENCE CHARACTERS

2: Thermosetting resin composition
3: Semiconductor wafer
5: Semiconductor chip (Semiconductor element)
16: Adherend
20: Semiconductor device

1. A thermosetting resin composition for producing a semiconductor device, the thermosetting resin composition comprising:
an epoxy resin; and
a novolak-type phenol resin having a hydroxyl equivalent of 200 g/eq or more.

2. The thermosetting resin composition according to claim 1, wherein the thermosetting resin composition is for sealing a semiconductor element.

3. The thermosetting resin composition according to claim 1, wherein the novolak-type phenol resin includes a structure represented by the following structural formula: 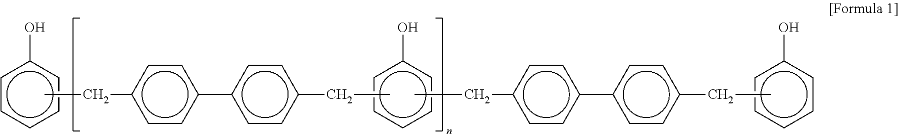
wherein n is an integer of 0 to 12.

4. The thermosetting resin composition according to claim 1, wherein the thermosetting resin composition comprises an inorganic filler having an average particle diameter of 10 nm or more and 1000 nm or less.

5. The thermosetting resin composition according to claim 1, wherein the thermosetting resin composition has a thermal expansion coefficient α of 10 ppm/K or more and 200 ppm/K or less after being heat-treated at 175° C. for 1 hour.

6. The thermosetting resin composition according to claim 1, wherein the thermosetting resin composition has a storage elastic modulus E′ of 100 MPa or more and 10000 MPa or less after being heat-treated at 175° C. for 1 hour.

7. The thermosetting resin composition according to claim 1, wherein the thermosetting resin composition is a sheet-like thermosetting resin composition.

8. A method for producing a semiconductor device, the method comprising:
a fixing step of fixing a semiconductor element to an adherend with the thermosetting resin composition according to claim 1 interposed therebetween; and
a curing step of curing the thermosetting resin composition.
